(19) United States
(12) Patent Application Publication
(10) Pub. No.: US 2024/0237477 A1
(43) Pub. Date: Jul. 11, 2024

(54) DISPLAY APPARATUS AND METHOD OF MANUFACTURING THE SAME

(71) Applicant: Samsung Display Co., LTD., Yongin-si (KR)

(72) Inventors: Hyuneok SHIN, Yongin-si (KR); Juhyun LEE, Yongin-si (KR); Joonyong PARK, Yongin-si (KR)

(21) Appl. No.: 18/368,150

(22) Filed: Sep. 14, 2023

(30) Foreign Application Priority Data
Jan. 11, 2023 (KR) 10-2023-004286

(51) Int. Cl. H10K 59/80; H10K 59/12

(52) U.S. Cl. CPC H10K 59/80517; H10K 59/1201

(57) ABSTRACT

A display apparatus includes a substrate, a first pixel electrode disposed on the substrate and including a transparent electrode layer having a first extinction coefficient at a pre-determined wavelength, a counter electrode disposed on the first pixel electrode, a first emission layer disposed between the first pixel electrode and the counter electrode, and a first oxide semiconductor layer disposed between the first pixel electrode and the first emission layer, and having a second extinction coefficient less than the first extinction coefficient at the pre-determined wavelength.

This application claims priority to Korean Patent Application No. 10-2023-0004286, filed on Jan. 11, 2023, and all the benefits accruing therefrom under 35 U.S.C. § 119, the content of which in its entirety is herein incorporated by reference.

### BACKGROUND

### 1. Field

Embodiments relate to a display apparatus and a method of manufacturing the same, and more particularly, to a display apparatus capable of minimizing a decrease in light efficiency caused by an optical resonance structure and a method of manufacturing the display apparatus.

### 2. Description of the Related Art

A display apparatus receives information about an image and displays the image. A display apparatus is used for a relatively small product such as a mobile phone or for a relatively large product such as a television.

A display apparatus includes a plurality of pixels that emit light by receiving an electrical signal to display an image to the outside. Each pixel includes a light-emitting device. For example, an organic light-emitting display apparatus includes an organic light-emitting diode (“OLED”) as a light-emitting device. In general, in the organic light-emitting display apparatus, a thin-film transistor and the OLED are formed on a substrate, and the OLED emits light by itself.

A display apparatus for displaying a full-color image by using the OLED employs an optical resonance structure in which an optical length of each wavelength emitted from an emission layer of each pixel having a different color is changed.

### SUMMARY

Embodiments include a display apparatus capable of minimizing a decrease in light efficiency caused by an optical resonance structure and a method of manufacturing the display apparatus. However, the embodiments are examples, and do not limit the scope of the disclosure.

Additional features will be set forth in part in the description which follows and, in part, will be apparent from the description, or may be learned by practice of the presented embodiments.

In an embodiment of the disclosure, a display apparatus includes a substrate, a first pixel electrode disposed on the substrate and including a transparent electrode layer having a first extinction coefficient at a pre-determined wavelength, a counter electrode disposed on the first pixel electrode, a first emission layer disposed between the first pixel electrode and the counter electrode, and a first oxide semiconductor layer disposed between the first pixel electrode and the first emission layer, and having a second extinction coefficient less than the first extinction coefficient at the pre-determined wavelength.

In an embodiment, the second extinction coefficient may be a positive number of 0.0001 or less at a wavelength of 550 nanometers.

In an embodiment, the transparent electrode layer may include indium tin oxide (“ITO”), and the first oxide semiconductor layer may include indium gallium zinc oxide (“IGZO”).

In an embodiment, a thickness of the first oxide semiconductor layer may be greater than a thickness of the transparent electrode layer.

In an embodiment, the display apparatus may further include a metal oxide layer disposed between the first oxide semiconductor layer and the first emission layer.

In an embodiment, the metal oxide layer may include tungsten oxide (WOₓ).

In an embodiment, a thickness of the metal oxide layer may be less than a thickness of the first oxide semiconductor layer.

In an embodiment, the metal oxide layer may contact a top surface of the first oxide semiconductor layer.

In an embodiment, the transparent electrode layer may include a 1-1^{th} transparent electrode layer disposed on the substrate, a first reflective layer disposed on the 1-1^{th} transparent electrode layer, and a 2-1^{th} transparent electrode layer disposed on the first reflective layer and including a same material as a material of the 1-1^{th} transparent electrode layer.

In an embodiment, the display apparatus may further include a second pixel electrode disposed on the substrate, spaced apart from the first pixel electrode in a direction parallel to a top surface of the substrate, and disposed under the counter electrode, and a second emission layer disposed between the second pixel electrode and the counter electrode.

In an embodiment, the metal oxide layer may be disposed between the second pixel electrode and the second emission layer.

In an embodiment, a distance between the first emission layer and the top surface of the substrate may be greater than a distance between the second emission layer and the top surface of the substrate.

In an embodiment, the metal oxide layer may contact a top surface of the second pixel electrode.

In an embodiment, the display apparatus may further include a pixel-defining film covering an edge of each of the first pixel electrode and the second pixel electrode.

In an embodiment, the metal oxide layer may cover a top surface of the pixel-defining film.

In an embodiment of the disclosure, a method of manufacturing a display apparatus includes forming a pixel circuit layer including at least one thin-film transistor on a substrate, forming, on the pixel circuit layer, a pixel electrode layer including a transparent electrode layer having a first extinction coefficient at a pre-determined wavelength, forming, on the pixel electrode layer, an oxide semiconductor layer having a second extinction coefficient less than the first extinction coefficient at the pre-determined wavelength, and forming a plurality of pixel electrodes including at least a first pixel electrode and a second pixel electrode, and forming a first oxide semiconductor layer covering a top surface of the first pixel electrode, by performing an etching process on the pixel electrode layer and the oxide semiconductor layer.

In an embodiment, the method may further include forming a pixel-defining film covering an edge of the second pixel electrode and an edge of the first oxide semiconductor layer and exposing at least a central portion of the first oxide semiconductor layer and at least a central portion of the second pixel electrode.

In an embodiment, the method may further include forming a metal oxide layer covering the at least central portion of the first oxide semiconductor layer, the at least central portion of the second pixel electrode, and a top surface of the pixel-defining film.

In an embodiment, the forming of the oxide semiconductor layer may include locating a target including indium, gallium, and zinc in a chamber, and performing a sputtering process using sputtering gas including inert gas and oxygen gas on the target.

In an embodiment, a volume ratio of the oxygen gas to the inert gas injected into the chamber may range from about 1:9 to about 2:8.

### BRIEF DESCRIPTION OF THE DRAWINGS

The above and other features and advantages of illustrative embodiments will be more apparent from the following description taken in conjunction with the accompanying drawings, in which:

FIG. 1 is a plan view schematically illustrating an embodiment of a display panel of a display apparatus;

FIG. 2 is an equivalent circuit diagram illustrating a pixel included in the display panel of FIG. 1;

FIG. 3 is a cross-sectional view schematically illustrating a part of the display panel of FIG. 1;

FIG. 4A is a cross-sectional view schematically illustrating a periphery of a first pixel electrode of the display panel of FIG. 1, and FIG. 4B is an enlarged view of a portion AA of FIG. 4A;

FIG. 5A is a cross-sectional view schematically illustrating a periphery of a second pixel electrode of the display panel of FIG. 1, and FIG. 5B is an enlarged view of a portion BB of FIG. 5A;

FIG. 6 is a cross-sectional view schematically illustrating a part of a display panel of a display apparatus, according to a comparative example;

FIGS. 7 to 13 are cross-sectional views sequentially illustrating another embodiment of a part of a display apparatus according to a method of manufacturing a display apparatus;

FIG. 14 is a graph showing a refractive index and an extinction coefficient of an oxide semiconductor layer included in a display apparatus of an embodiment according to a wavelength;

FIG. 15 is a graph showing a refractive index and an extinction coefficient of indium gallium zinc oxide (“IGZO”) of a comparative example according to a wavelength;

FIG. 16 is a graph showing a refractive index and an extinction coefficient of indium tin oxide (“ITO”) of a comparative example according to a wavelength; and

FIG. 17 is a graph showing electrical characteristics of a pixel electrode (case 1) included in an embodiment of a display apparatus and including a surface so that a metal oxide layer including WOₓ is deposited on an entirety of the surface, and electrical characteristics of a pixel electrode (case 2) in which a metal oxide layer is not deposited.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, illustrative embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, where the same or corresponding elements are denoted by the same reference numerals throughout and a repeated description thereof is omitted.

It will be understood that when a component, such as a layer, a film, a region, or a plate, is referred to as being “on” another component, the component may be directly on the other component or intervening components may be therebetween. Also, sizes of components in the drawings may be exaggerated or contracted for convenience of explanation. For example, because sizes and thicknesses of elements in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

A display apparatus in an embodiment will be described in detail based on the above descriptions.

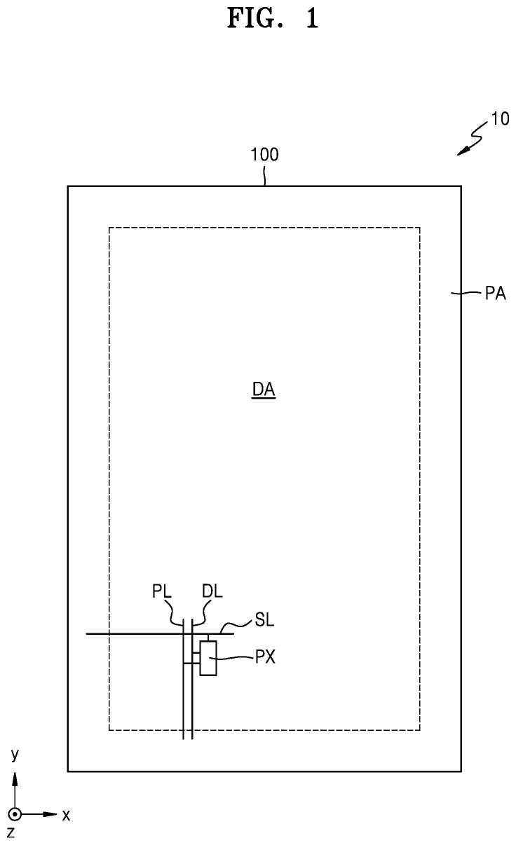

FIG. 1 is a plan view schematically illustrating an embodiment of a display panel of a display apparatus.

As shown in FIG. 1, a display apparatus in an embodiment may include a display panel 10. The display apparatus may be any display apparatus as long as it includes the display panel 10. In an embodiment, the display apparatus may be any of various apparatuses such as a smartphone, a tablet, a laptop, a television, or a billboard, for example. The display apparatus in an embodiment includes thin-film transistors (“TFTs”) and a capacitor, and the thin-film transistors and the capacitor may be implemented by conductive layers and insulating layers.

The display panel 10 includes a display area DA and a peripheral area PA disposed outside the display area DA. In FIG. 1, the display area DA has a quadrangular shape, e.g., rectangular shape. However, the disclosure is not limited thereto. The display area DA may have any of various shapes such as a circular shape, an elliptical shape, a polygonal shape, or a predetermined shape.

The display area DA is a portion where an image is displayed, and a plurality of pixels PX may be disposed in the display area DA. Each pixel PX may include a display device such as an organic light-emitting diode. Each pixel PX may emit, e.g., red light, green light, or blue light. The pixel PX may be connected to a pixel circuit including a TFT and a storage capacitor. The pixel circuit may be connected to a scan line SL that transmits a scan signal, a data line DL that intersects the scan line SL and transmits a data signal, and a driving voltage line PL that supplies a driving voltage. The scan line SL may extend in an x-direction (hereinafter, also referred to as a second direction), and the data line DL and the driving voltage line PL may extend in a y-direction (hereinafter, also referred to as a first direction).

The pixel PX may emit light having a luminance corresponding to an electrical signal from the pixel circuit that is electrically connected. The display area DA may display a predetermined image through light emitted from the pixel PX. For reference, the pixel PX may be defined as an emission area that emits light of any one color from among red, green, and blue as described above.

The peripheral area PA is a portion where the pixel PX is not disposed and an image is not displayed. In the peripheral area PA, a power supply wiring for driving the pixel PX may be disposed. Also, in the peripheral area PA, pads may be disposed, and an integrated circuit device such as a driver integrated circuit (“IC”) or a printed circuit board including a driving circuit unit may be electrically connected to the plurality of pads.

For reference, because the display panel 10 includes a substrate 100, the substrate 100 may include the display area DA and the peripheral area PA. The substrate 100 will be described below in detail.

Also, a plurality of transistors may be disposed in the display area DA. In the plurality of transistors, a first terminal of the transistor may be a source electrode or a drain electrode, and a second terminal may be an electrode different from the first terminal, according to a type (N-type or P-type) and/or an operating condition of the transistor. In an embodiment, when the first terminal is a source electrode, the second terminal may be a drain electrode, for example.

The plurality of transistors may include a driving transistor, a data write transistor, a compensation transistor, an initialization transistor, and an emission control transistor. The driving transistor may be connected between the driving voltage line PL and an organic light-emitting diode OLED, and the data write transistor may be connected to the data line DL and the driving transistor, and may perform a switching operation of transmitting a data signal transmitted through the data line DL.

The compensation transistor may be turned on according to a scan signal received through the scan line S to connect the driving transistor to the organic light-emitting diode OLED and compensate for a threshold voltage of the driving transistor.

The initialization transistor may be turned on according to a scan signal received through the scan line SL to transmit an initialization voltage to a gate electrode of the driving transistor and initialize the gate electrode of the driving transistor. The scan line connected to the initialization transistor may be a scan line different from the scan line connected to the compensation transistor.

The emission control transistor may be turned on according to an emission control signal received through an emission control line, and thus, driving current may flow through the organic light-emitting diode OLED.

The organic light-emitting diode OLED may include a pixel electrode (anode) and a counter electrode (cathode), and the counter electrode 170 may receive a second power supply voltage ELVSS. The organic light-emitting diode OLED may receive the driving current from the driving transistor to emit light and display an image.

Hereinafter, although an organic light-emitting display apparatus is described as a display apparatus in an embodiment, the display apparatus of the disclosure is not limited thereto. In another embodiment, the display apparatus may be an inorganic light-emitting display apparatus or an inorganic electroluminescent (“EL”) display apparatus, or a quantum dot light-emitting display apparatus. In an embodiment, an emission layer of a display device included in the display apparatus may include an organic material or an inorganic material, for example. Also, the display apparatus may include an emission layer, and quantum dots disposed in a path of light emitted from the emission layer.

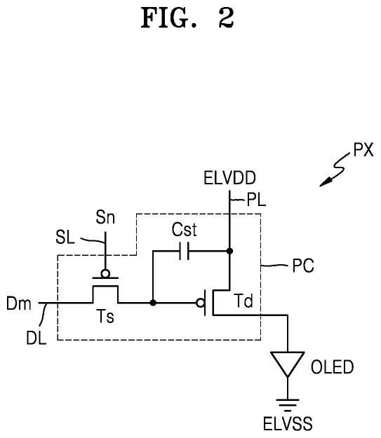

FIG. 2 is an equivalent circuit diagram illustrating a pixel included in the display panel of FIG. 1.

As shown in FIG. 2, each pixel PX includes a pixel circuit PC connected to the scan line SL and the data line DL, and an organic light-emitting diode OLED connected to the pixel circuit PC. The pixel circuit PC includes a driving TFT Td, a switching TFT Ts, and a storage capacitor Cst. The switching TFT Ts is connected to the scan line SL and the data line DL, and transmits a data signal Dm input through the data line DL to the driving TFT Td according to a scan signal Sn input through the scan line SL.

The storage capacitor Cst is connected to the switching TFT Ts and the driving voltage line PL, and stores a voltage corresponding to a difference between a voltage received from the switching TFT Ts and a first power supply voltage ELVDD supplied to the driving voltage line PL. The second power supply voltage ELVSS may be a driving voltage having a lower level than the first power supply voltage ELVDD. A level of a driving voltage supplied to each pixel PX may be a difference between a level of the first power supply voltage ELVDD and a level of the second power supply voltage ELVSS.

The driving TFT Td may be connected to the driving voltage line PL and the storage capacitor Cst, and may control driving current flowing through the organic light-emitting diode OLED from the driving voltage line PL in response to a value of the voltage stored in the storage capacitor Cst. The organic light-emitting diode OLED may emit light having a predetermined luminance due to the driving current.

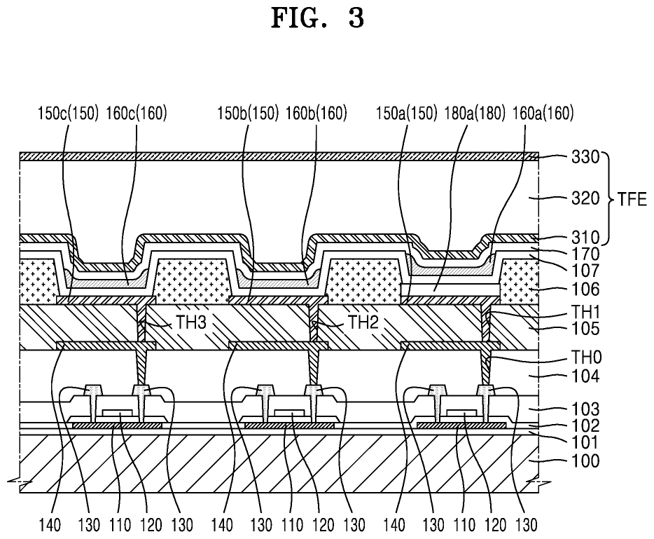

FIG. 3 is a cross-sectional view schematically illustrating a part of the display panel of FIG. 1.

The substrate 100 may include portions corresponding to the display area DA and the peripheral area PA outside the display area as described above. The substrate 100 may include any of various flexible or bendable materials. In an embodiment, the substrate 100 may include glass, a metal, or a polymer resin, for example. Also, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. However, various modifications may be made. In an embodiment, the substrate 100 may have a multi-layer structure including two layers each including a polymer resin and a barrier layer including an inorganic material (e.g., silicon oxide, silicon nitride, or silicon oxynitride) and disposed between the two layers, for example.

A buffer layer 101 may be disposed on the substrate 100. The buffer layer 101 may serve as a barrier layer and/or a blocking layer for preventing diffusion of impurity ions, preventing penetration of moisture or external air, and planarizing a surface. The buffer layer 101 may include silicon oxide, silicon nitride, or silicon oxynitride. Also, the buffer layer 101 may adjust a heat supply rate during a crystallization process for forming a semiconductor layer 110 so that the semiconductor layer 110 is uniformly crystalized.

The semiconductor layer 110 may be disposed on the buffer layer 101. The semiconductor layer 110 may include or consist of polysilicon, and may include a channel region not doped with impurities and a source region and a drain region on opposite sides of the channel region and doped with impurities. The impurities may vary according to a type of a TFT, and may be N-type impurities or P-type impurities.

A gate insulating film 102 may be disposed on the semiconductor layer 110. The gate insulating film 102 may be an element for ensuring insulation between the semiconductor layer 110 and a gate layer 120. The gate insulating film 102 may include an inorganic material such as silicon oxide, silicon nitride, and/or silicon oxynitride, and may be disposed between the semiconductor layer 110 and the gate layer 120. Also, the gate insulating film 102 may be formed to correspond to an entirety of the surface of the substrate 100, and may have a structure in which contact holes are formed at pre-set portions. As such, an insulating film including an inorganic material may be formed by chemical vapor deposition (“CVD”) or atomic layer deposition (“ALD”). This applies to the following embodiments and modifications thereof.

The gate layer 120 may be disposed on the gate insulating film 102. The gate layer 120 may vertically overlap the semiconductor layer 110, and may include at least one metal from among molybdenum (Mo), aluminum (Al), platinum (Pt), palladium (Pd), silver lithium (Li), calcium (Ca), titanium (Ti), tungsten (W), and copper (W).

An inter-insulating film 103 may be disposed on the gate layer 120. The inter-insulating film 103 may cover the gate layer 120. The inter-insulating film 103 may include or consist of an inorganic material. In an embodiment, the inter-insulating film 103 may include or consist of a metal oxide or a metal nitride, for example. In detail, the inorganic material may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZrO₂). The inter-insulating film 103 may have a double structure including or consisting of SiOₓ/SiN_{y} or SiNₓ/SiO_{y} in some embodiments.

A first conductive layer 130 may be disposed on the inter-insulating film 103. The first conductive layer 130 may function as an electrode connected to the source/drain region of the semiconductor layer through a through-hole defined in the inter-insulating film 103. The first conductive layer 130 may include at least one metal selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In an embodiment, the first conductive layer 130 may include a Ti layer, an Al layer, and/or a Cu layer, for example.

A first organic insulating layer 104 may be disposed on the first conductive layer 130. The first organic insulating layer 104 may be an organic insulating layer functioning as a planarization film covering the first conductive layer 130 and having a substantially flat top surface. The first organic insulating layer 104 may include, e.g., an organic material such as acryl, benzocyclobutene (“BCB”), or hexamethyldisiloxane (“HMDSO”). Various modifications may be made. In an embodiment, the first organic insulating layer 104 may have a single or multi-layer structure, for example.

A second conductive layer 140 may be disposed on the first organic insulating layer 104. The second conductive layer 140 may function as an electrode connected to the source/drain region of the semiconductor layer through a through-hole TH0 defined in the first organic insulating layer 104. The second conductive layer 140 may include at least one metal selected from among aluminum (Al), platinum (Pt), palladium (Pd), silver lithium (Li), calcium (Ca), molybdenum (Mo), titanium (Ti), tungsten (W), and copper (Cu). In an embodiment, the second conductive layer 140 may include a Ti layer, an Al layer, and/or a Cu layer, for example.

A second organic insulating layer 105 may be disposed on the first conductive layer 130. The second organic insulating layer 105 may be an organic insulating layer functioning as a planarization film covering the first conductive layer 130 and having a substantially flat top surface. The second organic insulating layer 105 may include, e.g., an organic material such as acryl, benzocyclobutene (“BCB”), or hexamethyldisiloxane (“HMDSO”). Various modifications may be made. In an embodiment, the second organic insulating layer 105 may have a single or multi-layer structure, for example.

Also, although not shown in FIG. 3, an additional conductive layer and an additional insulating layer may be disposed between a conductive layer and a pixel electrode, and may be applied to various embodiments. In this case, the additional conductive layer and the conductive layer may include the same material and may have the same layer structure. The additional insulating layer the organic insulating layer may include the same material and have the same layer structure.

A pixel electrode 150 may be disposed on the second organic insulating layer 105. The pixel electrode 150 may be connected to the second conductive layer 140 through contact holes TH1, TH2, and TH3 defined in the second organic insulating layer 105. A display device may be disposed on the pixel electrode 150. An organic light-emitting diode OLED may be used as the display device. That is, the organic light-emitting diode OLED may be disposed on, e.g., the pixel electrode 150. The pixel electrode 150 may include a light-transmitting conductive layer including or consisting of a light-transmitting conductive oxide such as indium tin oxide (“ITO”), In₂O₃, or indium zinc oxide (“IZO”), and a reflective layer including or consisting of a metal such as Al or Ag. In an embodiment, the pixel electrode 150 may have a three-layer structure including ITO/Ag/ITO, for example.

In addition, the pixel electrode 150 may be described as being disposed on the substrate 100. This is for convenience of explanation, and the buffer layer 101, the semiconductor layer 110, the gate insulating film 102, the gate layer 120, the inter-insulating film 103, the first conductive layer 130, the first organic insulating layer 104, and the second organic insulating layer 105 may be disposed between the pixel electrode 150 and the substrate 100.

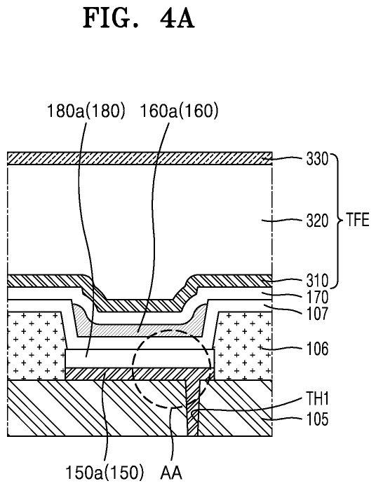

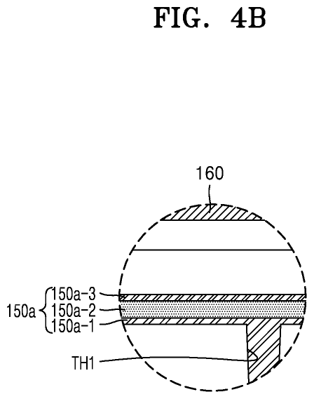

In addition, as described below with reference to FIGS. 4A and 4B, the pixel electrode 150 may include a plurality of conductive layers, which will be described below in detail.

The pixel electrode 150 may include a plurality of pixel electrodes corresponding to pixels of different wavelength bands. The plurality of pixel electrodes may include at least a first pixel electrode 150a, a second pixel electrode 150b, and a third pixel electrode 150c.

Each of the plurality of pixel electrodes may be disposed on the substrate 100, and may include a transparent electrode layer having a first extinction coefficient at a pre-determined wavelength. In this case, the transparent electrode layer may include indium tin oxide (“ITO”). Hereinafter, it is assumed that all extinction coefficients mentioned herein are measured under the same conditions. In an embodiment, the extinction coefficients may be values measured or calculated by light of the same wavelength band under room temperature and actual humidity conditions, for example.

The first pixel electrode 150a may be disposed on the substrate 100, may include the transparent electrode layer having the first extinction coefficient at the pre-determined wavelength, and may be disposed under the counter electrode 170 described below.

The second pixel electrode 150b may be disposed on the substrate 100, may be spaced apart from the first pixel electrode 150a in a direction parallel to a top surface of the substrate 100, and may be disposed under the counter electrode 170 described below.

The third pixel electrode 150c may be disposed on the substrate 100, may be spaced apart from the first pixel electrode 150a and the second pixel electrode 150b in a direction parallel to the top surface of the substrate 100, and may be disposed under the counter electrode 170 described below. When viewed in a direction perpendicular to the substrate 100, the second pixel electrode 150b may be disposed between the first pixel electrode 150a and the third pixel electrode 150c.

An oxide semiconductor layer 180 may be disposed on at least some of the plurality of pixel electrodes. In detail, a first oxide semiconductor layer 180a among the oxide semiconductor layers 180 may be disposed on the first pixel electrode 150a. When desired, the oxide semiconductor layer 180 may not be disposed on the second pixel electrode 150b and/or the third pixel electrode 150c. When desired, the oxide semiconductor layer 180 may further include at least a second oxide semiconductor layer (not shown) disposed on a fourth pixel electrode (not shown) and a third oxide semiconductor layer (not shown) disposed on a fifth pixel electrode (not shown). In this case, at least the first oxide semiconductor layer 180a to the third oxide semiconductor layer (not shown) having the same thickness may be disposed, and the first oxide semiconductor layer 180a to the third oxide semiconductor layer (not shown) having the same thickness may be layers corresponding to emission layers generating the same wavelength band.

In an embodiment, pixel electrodes corresponding to emission layers generating blue-based light, and at least the first oxide semiconductor layer 180a to the third oxide semiconductor layer (not shown) may be disposed between the emission layers generating blue-based light and the pixel electrodes, for example. Although not shown for convenience of explanation, an n^{th} oxide semiconductor layer may be further disposed. The first oxide semiconductor layer 180a will be representatively described from among the oxide semiconductor layers 180, and the description of the first oxide semiconductor layer 180a may be applied to the n^{th} oxide semiconductor layer.

The oxide semiconductor layer 180 may form an optical resonance structure for a desired optical distance. When desired, the n^{th} oxide semiconductor layer may be disposed on the plurality of pixel electrodes, or may be disposed only on some pixel electrodes. In some cases, a thickness of the oxide semiconductor layer may vary as desired.

The oxide semiconductor layer 180 that is a transparent layer may be disposed under an intermediate layer 160 described below. That is, the oxide semiconductor layer 180 may be disposed between the pixel electrode 150 and the intermediate layer 160. The oxide semiconductor layer 180 may be disposed between the pixel electrode 150 and a first emission layer 160a included in the intermediate layer 160.

The oxide semiconductor layer 180 may include indium gallium zinc oxide (“IGZO”), and may be formed by a sputtering process. In particular, sputtering gas may be injected into a chamber during a sputtering process of the oxide semiconductor layer 180. A target including indium, gallium, or zinc may be disposed in the chamber.

The sputtering gas may include argon gas (Ar) and oxygen gas (O₂). In this case, a volume of the oxygen gas (O₂) included in the sputtering gas may occupy about 5% to about 70% of a volume of the chamber, and preferably, a volume of the oxygen gas (O₂) included in the sputtering gas may occupy 10% to 20% of a volume of the chamber. That is, a volume ratio of the oxygen gas to the argon gas in the chamber may range from about 1:9 to about 2:8.

Likewise, a standard cubic centimeters per minute (“SCCM”) ratio of the oxygen gas (O₂) to the argon gas (Ar) injected into the chamber may range from about 1:19 to about 7:3, and preferably, an SCCM ratio of the oxygen gas (O₂) to the argon gas (Ar) injected into the chamber may range from about 1:9 to about 1:4 of a volume of the chamber.

As such, the oxide semiconductor layer 180 formed by performing a sputtering process by sputtering gas including oxygen may have a second extinction coefficient having the maximum value of a positive number of about 0.0001 or less at a wavelength of about 550 nanometers (nm). In this case, the second extinction coefficient may be less than the first extinction coefficient of the transparent electrode layer including ITO. The first extinction coefficient may be between about 0.05 nm and 0.1 at about 550 nm.

A thickness of the oxide semiconductor layer 180 may be determined by a desired optical distance. In an embodiment, a thickness of the oxide semiconductor layer 180 may preferably be about 800 angstroms (Å), for example.

A pixel-defining film 106 may be disposed on the second organic insulating layer 105, to cover an edge of the pixel electrode 150. That is, the pixel-defining film 106 may cover an edge of each of the plurality of pixel electrodes. The pixel-defining film 106 may define an opening corresponding to the pixel PX, and at least a central portion of the pixel electrode 150 may be exposed through the opening. The pixel-defining film 106 may include an organic material such as polyimide or hexamethyldisiloxane (“HMDSO”). In an embodiment, the pixel-defining film may cover an edge of each of the first pixel electrode 150a and the second pixel electrode 150b, for example.

A spacer (not shown) may be disposed on the pixel-defining film 106. Although the spacer (not shown) is disposed in the peripheral area PA, the spacer may be disposed in the display area DA. The spacer (not shown) may prevent the organic light-emitting diode OLED from being damaged due to sagging of a mask during a manufacturing process using the mask. The spacer (not shown) may include an organic insulating material, and may have a single or multi-layer structure.

A metal oxide layer 107 may be disposed on the oxide semiconductor layer 180 including at least the first oxide semiconductor layer 180a. The metal oxide layer 107 may be disposed on the pixel-defining film. The metal oxide layer 107 may contact a top surface of the oxide semiconductor layer 180. In this case, a thickness of the metal oxide layer 107 may be less than a thickness of the oxide semiconductor layer 180.

In detail, the metal oxide layer 107 may cover a top surface of the pixel-defining film, and may cover a top surface of the oxide semiconductor layer 180 exposed through the pixel-defining films. The metal oxide layer 107 may cover an inner surface of the opening of the pixel-defining film. In this case, at least a part of the top surface of the oxide semiconductor layer 180 may be exposed through the opening of the pixel-defining film.

The metal oxide layer 107 may cover a top surface of the pixel electrode exposed between the pixel-defining films. In this case, the oxide semiconductor layer 180 may not be disposed on the top surface of the pixel electrode contacting the metal oxide layer 107.

In an embodiment, the metal oxide layer 107 may cover a top surface of the oxide semiconductor layer 180 disposed on the first pixel electrode 150a, for example. In this case, the metal oxide layer 107 may be disposed between the oxide semiconductor layer 180 and the first emission layer 160a.

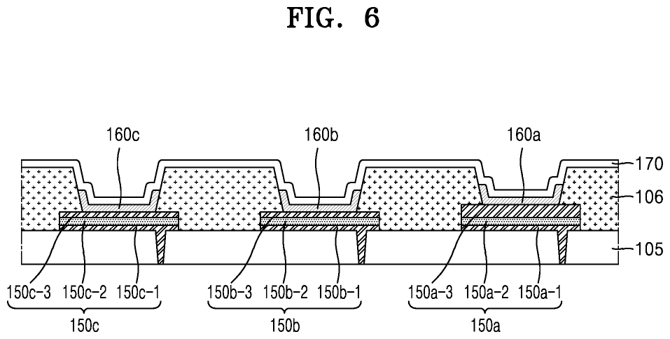

The metal oxide layer 107 may cover a top surface of the second pixel electrode 150b. The metal oxide layer 107 may cover a top surface of the pixel electrode not covered by the oxide semiconductor layer 180. In this case, the metal oxide layer 107 may be disposed between a 2-2^{th} transparent electrode layer 150b-3 (refer to FIG. 6) of the second pixel electrode 150b and a second emission layer 160b.

The metal oxide layer 107 may cover a top surface of the third pixel electrode 150c. The metal oxide layer 107 may cover a top surface of the pixel electrode not covered by the oxide semiconductor layer 180. In this case, the metal oxide layer 107 may be disposed between a 2-3^{th} transparent electrode layer 150c-3 (refer to FIG. 6) of the third pixel electrode 150c and a third emission layer 160c.

The metal oxide layer 107 may contact the top surface of the first oxide semiconductor layer 180a disposed on the first pixel electrode 150a. The metal oxide layer 107 may contact at least a part of the top surface of the second pixel electrode 150b. The metal oxide layer 107 may contact at least a part of the top surface of the third pixel electrode 150c.

The metal oxide layer 107 may contact a top surface of the pixel electrode exposed between pixel-defining films of the plurality of pixel electrodes. The metal oxide layer 107 may contact a top surface of the oxide semiconductor layer exposed between pixel-defining films.

In an embodiment, the metal oxide layer 107 may include tungsten oxide (WOₓ), for example. When the metal oxide layer 107 includes tungsten oxide (WOₓ), holes may be more smoothly injected into the first to third emission layers 160a, 160b, and 160c.

In detail, hole injection characteristics of a pixel electrode when an optical thickness is adjusted by an IGZO thin film may be lower than when an optical thickness is adjusted by increasing a thickness of an ITO layer. In this case, when the metal oxide layer 107 including tungsten oxide (WOₓ) is added as in an embodiment, hole injection characteristics of the pixel electrode may be improved.

In an embodiment, the metal oxide layer 107 including tungsten oxide (WOₓ) may be deposited on an entirety of the surface without a separate etching process, and a thickness of the metal oxide layer 107 may be about 50 angstroms (Å), for example. The metal oxide layer 107 including tungsten oxide (WOₓ) may prevent a driving voltage lagging phenomenon occurring in the oxide semiconductor layer 180 including zinc (Zn), which will be described below.

The intermediate layer 160 and the counter electrode 170 may be disposed in the opening of the pixel-defining film 106. Also, the intermediate layer 160 may be disposed on the metal oxide layer 107. The intermediate layer 160 may include a relatively low molecular weight material or a relatively high molecular weight material. When the intermediate layer 160 includes a relatively low molecular weight material, the intermediate layer 160 may include a hole injection layer, a hole transport layer, the first to third emission layers 160a, 160b, and 160c, an electron transport layer, and/or an electron injection layer. When the intermediate layer 160 includes a relatively high molecular weight material, the intermediate layer 160 may generally have a structure including a hole transport layer and an emission layer.

In addition, the first to third emission layers 160a, 160b, and 160c included in the intermediate layer 160 may be a plurality of emission layers respectively corresponding to the plurality of pixel electrodes. In detail, the plurality of emission layers may include at least the first emission layer 160a, the second emission layer 160b, and the third emission layer 160c. The plurality of emission layers may be disposed under the counter electrode 170 described below. That is, the plurality of emission layers may be disposed between the pixel electrodes and the counter electrode 170, and the first emission layer 160a from among the plurality of emission layers may be disposed between the oxide semiconductor layer 180 and the counter electrode 170. The first emission layer 160a from among the plurality of emission layers may be disposed between the metal oxide layer 107 and the counter electrode 170.

The first emission layer 160a may be disposed on the first pixel electrode 150a, the second emission layer 160b may be disposed on the second pixel electrode 150b, and the third emission layer 160c may be disposed on the third pixel electrode 150c. When desired, the first emission layer 160a and the second emission layer 160b may emit light of different wavelength regions.

The first emission layer 160a may emit light of a first wavelength region. The first emission layer 160a may be disposed between the first pixel electrode 150a and the counter electrode 170. In an embodiment, the first emission layer 160a may emit blue-based visible light, for example. However, a type of visible light of the first emission layer 160a is merely one of embodiments, and does not limit the scope of the disclosure.

The second emission layer 160b may emit light of a second wavelength region. The second emission layer 160b may be disposed between the second pixel electrode 150b and the counter electrode 170. In an embodiment, the second emission layer 160b may emit red or green-based visible light, for example. However, a type of visible light of the second emission layer 160b is merely one of embodiments, and does not limit the scope of the disclosure.

The third emission layer 160c may emit light of a third wavelength region. The third emission layer 160c may be disposed between the third pixel electrode 150c and the counter electrode 170. In an embodiment, the third emission layer 160c may emit red or green-based visible light, for example. A color of visible light emitted by the third emission layer 160c may be the same as or different from a color of visible light emitted by the second emission layer 160b. However, a type of visible light of the third emission layer 160c is merely one of embodiments, and does not limit the scope of the illustrated embodiment.

The counter electrode 170 may include a light-transmitting conductive layer including or consisting of a light-transmitting conductive oxide such as ITO, In₂O₃, or IZO. The pixel electrode 150 is used as an anode, and the counter electrode 170 is used as a cathode. Polarities of the electrodes may be applied in reverse.

A structure of the intermediate layer 160 is not limited thereto, and may be any of various structures. In an embodiment, at least one of layers of the intermediate layer 160 may be unitary, like the counter electrode 170, for example. In another embodiment, the intermediate layer 160 may include a layer patterned to correspond to each of the plurality of pixel electrodes 150.

The counter electrode 170 may be disposed in the display area DA, and may be disposed over an entirety of the surface of the display area DA. That is, the counter electrode 170 may be unitary to cover a plurality of pixels. The counter electrode 170 may electrically contact a common power supply line (not shown) disposed in the peripheral area PA.

In an embodiment, the counter electrode 170 may extend to a blocking wall (not shown). A thin-film encapsulation layer TFE may cover the entirety of the display area DA, and may extend to the peripheral area PA to cover at least a part of the peripheral area PA.

In an embodiment, the counter electrode 170 may cover a plurality of emission layers including at least the first emission layer 160a, the second emission layer 160b, and the third emission layer 160c. In other words, the plurality of emission layers including at least the first emission layer 160a, the second emission layer 160b, and the third emission layer 160c may be disposed between the plurality of pixel electrodes and the counter electrode 170. The first emission layer 160a may be disposed between the first pixel electrode 150a and the counter electrode 170, the second emission layer 160b may be disposed between the second pixel electrode 150b and the counter electrode 170, and the third emission layer 160c may be disposed between the third pixel electrode 150c and the counter electrode 170.

A distance between the first emission layer 160a and a top surface of the substrate 100 may be greater than a distance between the second emission layer 160b and the top surface of the substrate 100. This is because the first oxide semiconductor layer 180a is disposed under the first emission layer 160a.

The thin-film encapsulation layer TFE may extend to the outside of the common power supply line (not shown). The thin-film encapsulation layer TFE may include a first inorganic encapsulation layer 310, a second inorganic encapsulation layer 330, and an organic encapsulation layer 320 disposed between the first inorganic encapsulation layer 310 and the second inorganic encapsulation layer 330. Each of the first and second inorganic encapsulation layers 310 and 330 may include at least one inorganic material from among aluminum oxide, titanium oxide, tantalum oxide, hafnium oxide, zinc oxide, silicon oxide, silicon nitride, and silicon oxynitride.

Each of the first inorganic encapsulation layer 310 and the second inorganic encapsulation layer 330 may have a single or multi-layer structure including the above material. The first inorganic encapsulation layer 310 and the second inorganic encapsulation layer 330 may include the same material or different materials. Thicknesses of the first inorganic encapsulation layer 310 and the second inorganic encapsulation layer 330 may be different from each other. A thickness of the first inorganic encapsulation layer 310 may be greater than a thickness of the second inorganic encapsulation layer 330. In an alternative embodiment, a thickness of the second inorganic encapsulation layer 330 may be greater than a thickness of the first inorganic encapsulation layer 310, or thicknesses of the first inorganic encapsulation layer 310 and the second inorganic encapsulation layer 330 may be the same.

The organic encapsulation layer 320 may include a monomer-based material or a polymer-based material. In embodiments, the polymer-based material may include an acrylic resin, an epoxy resin, polyimide, and polyethylene. In an embodiment, the organic encapsulation layer 320 may include acrylate.

The blocking wall (not shown) may be disposed in the peripheral area PA of the substrate 100. In an embodiment, the blocking wall (not shown) may include, but is not limited to, a part of the first organic insulating layer 104, a part of the second organic insulating layer 105, a part of the pixel-defining film 106, and a part of the spacer (not shown).

When desired, the blocking wall (not shown) may include only a part of the second organic insulating layer 105 or a part of the pixel-defining film 106. The blocking wall (not shown) may surround the display area DA, to prevent the organic encapsulation layer 320 of the thin-film encapsulation layer TFE from overflowing to the outside of the substrate 100. Accordingly, the organic encapsulation layer 320 may contact an inner surface of the blocking wall (not shown) facing the display area DA. In this case, when the organic encapsulation layer 320 contacts the inner surface of the blocking wall (not shown), it may mean that the first inorganic encapsulation layer 310 is disposed between the organic encapsulation layer 320 and the blocking wall (not shown) and the organic encapsulation layer 320 contacts the first inorganic encapsulation layer 310.

The first inorganic encapsulation layer 310 and the second inorganic encapsulation layer 330 may be disposed on the blocking wall (not shown), and may extend to an edge of the substrate 100. However, when desired, a plurality of blocking walls (not shown) may be provided.

FIG. 4A is a cross-sectional view schematically illustrating a periphery of a first pixel electrode of the display panel of FIG. 1, and FIG. 4B is an enlarged view of a portion AA of FIG. 4A.

As shown in FIG. 4A, the first oxide semiconductor layer 180a may be disposed on the first pixel electrode 150a. The pixel-defining film 106 may cover an edge of the first oxide semiconductor layer 180a, and may expose at least a part of a top surface of the first oxide semiconductor layer 180a. An intermediate layer including the first emission layer 160a may be disposed on the at least exposed part of the top surface of the first oxide semiconductor layer 180a, and the counter electrode 170 may be disposed on the intermediate layer and the pixel-defining film 106. Also, the metal oxide layer 107 may be disposed between the intermediate layer and the first oxide semiconductor layer 180a. The metal oxide layer 107 may cover a top surface of the pixel-defining film 106.

As shown in FIGS. 4A and 4B, the first pixel electrode 150a may include a plurality of layers. The first pixel electrode 150a may include a 1-1^{th} transparent electrode layer 150a-1 disposed on the substrate 100, a first reflective layer 150a-2 disposed on the 1-1^{th} transparent electrode layer 150a-1, and a 2-1^{th} transparent electrode layer 150a-3 disposed on the first reflective layer 150a-2. The 2-1^{th} transparent electrode layer 150a-3 may include the same material as that of the 1-1^{th} transparent electrode layer 150a-1.

A thickness of the first oxide semiconductor layer 180a may be greater than a thickness of the 1-1^{th} transparent electrode layer 150a-1. In an embodiment, a thickness of the 1-1^{th} transparent electrode layer 150a-1 may preferably be 100 Å, for example. The reason why a thickness of the first oxide semiconductor layer 180a is greater than a thickness of the 1-1^{th} transparent electrode layer 150a-1 is that a thickness of the first oxide semiconductor layer 180a is determined by a desired optical distance.

When an extinction coefficient of the first oxide semiconductor layer 180a that is thicker than the 1-1^{th} transparent electrode layer 150a-1 is similar to an extinction coefficient of the 1-1^{th} transparent electrode layer 150a-1, the first oxide semiconductor layer 180a may absorb more light than the transparent electrode layer. As a result, an extinction coefficient of the first oxide semiconductor layer 180a thicker than the 1-1^{th} transparent electrode layer 150a-1 may greatly affect the image quality of a display apparatus. Accordingly, it is preferable that a second extinction coefficient of the first oxide semiconductor layer 180a or the oxide semiconductor layer 180 which is a positive number of 0.0001 or less at a wavelength of about 550 nm is much less than a first extinction coefficient.

Also, a thickness of the first oxide semiconductor layer 180a may be greater than a thickness of the 2-1^{th} transparent electrode layer 150a-3. A thickness of the 2-1^{th} transparent electrode layer 150a-3 may be equal or similar to a thickness of the 1-1^{th} transparent electrode layer 150a-1.

The 1-1^{th} transparent electrode layer 150a-1 may include ITO. The 1-1^{th} transparent electrode layer 150a-1 may be disposed on a second organic insulating layer. The second organic insulating layer may include a first through-hole through which the 1-1^{th} transparent electrode layer 150a-1 is connected to a second conductive layer. Through the first through-hole, the 1-1^{th} transparent electrode layer 150a-1 may be electrically connected to the second conductive layer.

A thickness of the 1-1^{th} transparent electrode layer 150a-1 may be about 70 Å. The 1-1^{th} transparent electrode layer 150a-1 may cover an inner surface of the first through-hole of the second organic insulating layer. The 1-1^{th} transparent electrode layer 150a-1 may fill the first through-hole. A thickness of the 1-1^{th} transparent electrode layer 150a-1 measured from a top surface of the second organic insulating layer may be less than a thickness of a reflective layer.

The first reflective layer 150a-2 may be disposed on the 1-1^{th} transparent electrode layer 150a-1. That is, the first reflective layer 150a-2 may be disposed between the 1-1^{th} transparent electrode layer 150a-1 and the 2-1^{th} transparent electrode layer 150a-3. The first reflective layer 150a-2 may include a metal component such as Ag or Al, and may preferably include Ag. The first reflective layer 150a-2 including Ag may be suitable for dry etching used in a fine process. The first reflective layer 150a-2 may reflect light emitted from the first emission layer 160a included in the intermediate layer. When desired, the first reflective layer 150a-2 may fill at least a part of the first through-hole defined in the second organic insulating layer.

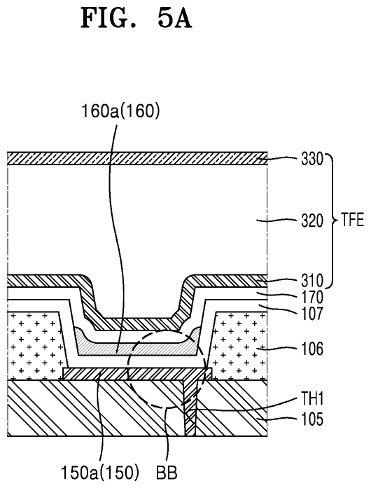

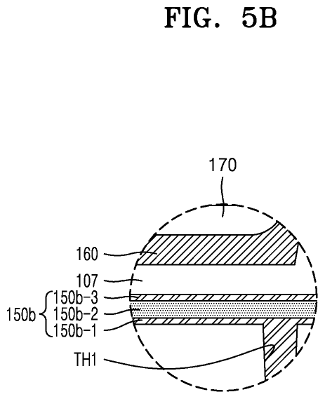

A thickness of the first reflective layer 150a-2 may be greater than a thickness of the 1-1^{th} transparent electrode layer 150a-1. A thickness of the first reflective layer 150a-2 may be about 1000 Å. A thickness of the first reflective layer 150a-2 may be greater than a thickness of a 1-2^{th} transparent electrode layer (150b-1 in FIG. 5B) described below. A thickness of the first reflective layer 150a-2 may be greater than a thickness of the first oxide semiconductor layer 180a. A thickness of the first reflective layer 150a-2 may be greater than a thickness of the metal oxide layer 107.

The 2-1^{th} transparent electrode layer 150a-3 may include ITO. The 2-1^{th} transparent electrode layer 150a-3 may be disposed on the reflective layer. A thickness of the 2-1^{th} transparent electrode layer 150a-3 may be equal to or greater than a thickness of the 1-1^{th} transparent electrode layer 150a-1.

FIG. 5A is a cross-sectional view schematically illustrating a periphery of a second pixel electrode of the display panel of FIG. 1, and FIG. 5B is an enlarged view of a portion BB of FIG. 5A.

As shown in FIGS. 5A and 5B, the second pixel electrode 150b may include a plurality of layers. The second pixel electrode 150b may include a 1-2^{th} transparent electrode layer 150b-1 disposed on the substrate 100, a second reflective layer 150b-2 disposed on the 1-2^{th} transparent electrode layer 150b-1, and a 2-2^{th} transparent electrode layer 150b-3 disposed on the second reflective layer 150b-2. The 2-2^{th} transparent electrode layer 150b-3 may include the same material as that of the 1-2^{th} transparent electrode layer 150b-1.

The 1-2^{th} transparent electrode layer 150b-1 may include ITO. The 1-2^{th} transparent electrode layer 150b-1 may be disposed on a second organic insulating layer. The second organic insulating layer may include a second through-hole through which the 1-2^{th} transparent electrode layer 150b-1 is connected to a second conductive layer. Through the second through-hole, the 2-1^{th} transparent electrode layer 150a-3 may be electrically connected to the second conductive layer.

A thickness of the 1-2^{th} transparent electrode layer 150b-1 may be about 70 Å. The 1-2^{th} transparent electrode layer 150b-1 may cover an inner surface of the second through-hole of the second organic insulating layer. The 1-2^{th} transparent electrode layer 150b-1 may fill the second through-hole. A thickness of the 1-2^{th} transparent electrode layer 150b-1 measured from a top surface of the second organic insulating layer may be less than a thickness of the second reflective layer 150b-2.

The second reflective layer 150b-2 may be disposed on the 1-2^{th} transparent electrode layer 150b-1. That is, the second reflective layer 150b-2 may be disposed between the 1-2^{th} transparent electrode layer 150b-1 and the 2-2^{th} transparent electrode layer 150b-3. The second reflective layer 150b-2 may include a metal component such as Ag or Al, and may preferably include Ag. The second reflective layer 150b-2 including Ag may be suitable for dry etching used in a fine process. The second reflective layer 150b-2 may reflect light emitted from the second emission layer 160b included in the intermediate layer. When desired, the second reflective layer 150b-2 may fill at least a part of the second through-hole defined in the second inorganic insulating layer.

A thickness of the second reflective layer 150b-2 may be greater than a thickness of the 1-2^{th} transparent electrode layer 150b-1. A thickness of the second reflective layer 150b-2 may be about 1000 Å. A thickness of the second reflective layer 150b-2 may be greater than a thickness of a 2-2^{th} transparent electrode layer 150b-3 described below. A thickness of the second reflective layer 150b-2 may be greater than a thickness of the metal oxide layer 107.

The 2-2^{th} transparent electrode layer 150b-3 may include ITO. The 2-2^{th} transparent electrode layer 150b-3 may be disposed on the second reflective layer 150b-2. A thickness of the 2-2^{th} transparent electrode layer 150b-3 may be equal to or greater than a thickness of the 1-2^{th} transparent electrode layer 150b-1.

FIG. 6 is a cross-sectional view schematically illustrating a part of a display panel of a display apparatus, according to a comparative example.

As shown in FIG. 6, the display panel of the display apparatus according to the comparative example may include a plurality of pixel electrodes disposed on a second organic insulating layer. The plurality of pixel electrodes may include at least the first pixel electrode 150a, the second pixel electrode 150b, and the third pixel electrode 150c.

Each of the plurality of pixel electrodes may include a plurality of layers. In an embodiment, the first pixel electrode 150a may include the 1-1^{th} transparent electrode layer 150a-1, the first reflective layer 150a-2, and the 2-1^{th} transparent electrode layer 150a-3, for example. The second pixel electrode 150b may include the 1-2^{th} transparent electrode 150b-1, the second reflective layer 150b-2, and the 2-2^{th} transparent electrode layer 150b-3. The third pixel electrode 150c may include a 1-3^{th} transparent electrode layer 150c-1, a third reflective layer 150c-2, and the 2-3^{th} transparent electrode layer 150c-3.

The display apparatus according to the comparative example may include an optical resonance structure. In this case, for the optical resonance structure, a thickness of the 2-1^{th} transparent electrode layer 150a-3 of the first pixel electrode 150a may be greater than a thickness of the 2-2^{th} transparent electrode layer 150b-3 of the second pixel electrode 150b. In an alternative embodiment, a thickness of the 2-1^{th} transparent electrode layer 150a-3 of the first pixel electrode 150a may be greater than a thickness of the 2-3^{th} transparent electrode layer 150c-3 of the third pixel electrode 150c.

The 2-1^{th} transparent electrode layer 150a-3 may include ITO, like the 1-1^{th} transparent electrode layer 150a-1. ITO may have an extinction coefficient between 0.05 to 0.1 in a visible light region. When a thickness of the 2-1^{th} transparent electrode layer 150a-3 including ITO having a relatively large extinction coefficient increases, a problem of increasing light absorption of reflective light may occur. That is, when a thickness of the 2-1^{th} transparent electrode layer 150a-3 increases, light absorption of the 2-1^{th} transparent electrode layer 150a-3 may increase in proportion to the thickness of the 2-1^{th} transparent electrode layer 150a-3.

However, in the display apparatus in the illustrated embodiment, because an optical distance for an optical resonance structure is adjusted by the oxide semiconductor layer 180a having an extinction coefficient less than an extinction coefficient of the 2-1^{th} transparent electrode layer 150a-3, light absorption may be minimized. In particular, a maximum value of an extinction coefficient of the oxide semiconductor layer 180 formed by a manufacturing method described below in a visible light region may be a positive number of 0.0001 or less.

A method of manufacturing a display apparatus (hereinafter, also referred to as a manufacturing method) in another embodiment will be described in detail based on the above description.

For reference, when the manufacturing method in another embodiment is described, the same or repeated description as that made for the display apparatus in an embodiment will be omitted.

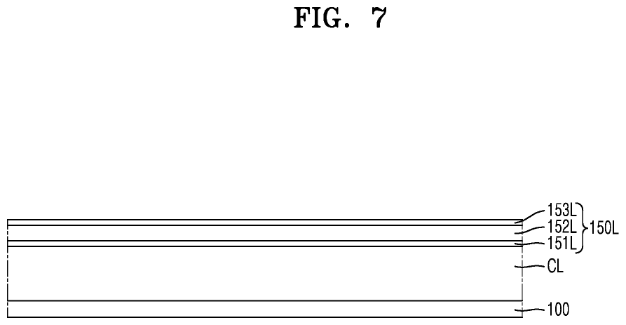

FIGS. 7 to 13 are cross-sectional views sequentially illustrating an embodiment of a part of a display apparatus according to a method of manufacturing a display apparatus.

Hereinafter, a method of depositing each layer in the manufacturing method in the illustrated embodiment may be at least one of a sputtering process, CVD, and ALD, unless otherwise described.

As shown in FIG. 7, the manufacturing method in the illustrated embodiment may include forming a pixel circuit layer CL including at least one TFT on the substrate 100, and forming a pixel electrode layer 150L including a transparent electrode layer having a first extinction coefficient at a pre-determined wavelength on the pixel circuit layer CL.

The pixel circuit layer CL including at least one TFT may be a plurality of layers included in the display apparatus in an embodiment named as one layer for convenience of explanation, and may refer to all layers disposed between the substrate 100 and a pixel electrode. That is, the pixel circuit layer CL may include at least one TFT.

In an embodiment, like in the display apparatus in an embodiment, the pixel circuit layer CL may include the buffer layer 101, the semiconductor layer 110, the gate insulating film 102, the gate layer 120, the inter-insulating film 103, the first conductive layer 130, the first organic insulating layer 104, the second conductive layer 140, and the second organic insulating layer 105, for example. When desired, the pixel circuit layer CL may further include an additional conductive layer and an additional organic insulating layer, like in an embodiment of the display apparatus.

The pixel electrode layer 150L including the transparent electrode layer having the first extinction coefficient at the pre-determined wavelength may include a first transparent electrode layer 151L, a reflective layer 152L disposed on the first transparent electrode layer 151L, and a second transparent electrode layer 153L disposed on the reflective layer 152L. In this case, the transparent electrode layer having the first absorption coefficient may refer to the first transparent electrode layer 151L and/or the second transparent electrode layer 153L. In an embodiment, the first transparent electrode layer 151L and the second transparent electrode layer 153L may include the same material (e.g., ITO) having the first extinction coefficient, for example.

Although not shown in FIG. 7, the second organic insulating layer that is an uppermost layer of the pixel circuit layer CL may define a plurality of through-holes through which the first transparent electrode layer 151L is connected to the second conductive layer. Through the plurality of through-holes, the first transparent electrode layer 151L may be electrically connected to the second conductive layer included in the pixel circuit layer CL. The first transparent electrode layer 151L may cover inner surfaces of the plurality of through-holes. For the plurality of through-holes, the same or repeated description as that made with reference to FIGS. 3 to 6 will be omitted.

In an embodiment, the first transparent electrode layer 151L may include ITO. The first transparent electrode layer 151L may be disposed on the pixel circuit layer CL (or the second organic insulating layer 105), for example. A thickness of the first transparent electrode layer 151L may be about 70 Å. A thickness of the first transparent electrode layer 151L may be less than a thickness of the reflective layer 152L.

The reflective layer 152L may be disposed on the first transparent electrode layer 151L. That is, the reflective layer 152L may be disposed between the first transparent electrode layer 151L and the second transparent electrode layer 153L. The reflective layer 152L may include a metal component such as silver (Ag) or aluminum (AI), and may preferably include Ag. The reflective layer 152L including Ag may be suitable for dry etching used in a fine process. The reflective layer 152L may reflect light emitted downward from an emission layer included in the intermediate layer. When desired, the reflective layer 152L may fill at least parts of the plurality of through-holes.

A thickness of the reflective layer 152L may be greater than a thickness of the first transparent electrode layer 151L. A thickness of the reflective layer 152L may be about 1000 Å. A thickness of the reflective layer 152L may be greater than a thickness of the second transparent electrode layer 153L described below. A thickness of the reflective layer 152L may be greater than a thickness of the oxide semiconductor layer 180 described below. A thickness of the reflective layer 152L may be greater than a thickness of the metal oxide layer 107 described below.

The second transparent electrode layer 153L may include ITO. The second transparent electrode layer 153L may be disposed on the reflective layer 152L. A thickness of the second transparent electrode layer 153L may be equal to or greater than a thickness of the first transparent electrode layer 151L.

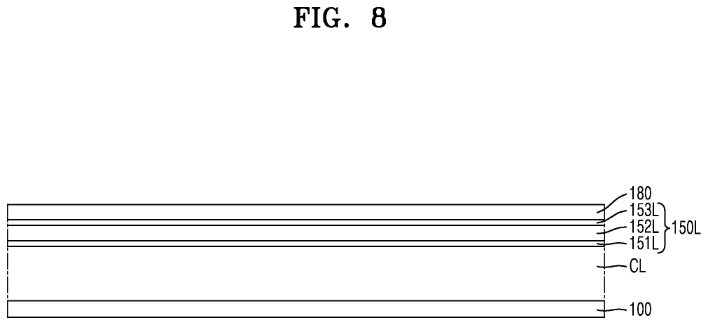

As shown in FIG. 8, the manufacturing method in the illustrated embodiment may further include forming the oxide semiconductor layer 180 having a second extinction coefficient less than the first extinction coefficient at the pre-determined wavelength on the pixel electrode layer 150L.

The oxide semiconductor layer 180 may form an optical distance for an optical resonance structure for a desired optical distance. The oxide semiconductor layer 180 that is a transparent layer may include indium gallium zinc oxide (“IGZO”), and may be formed by a sputtering process. In particular, sputtering gas may be injected into a chamber during a sputtering process of the oxide semiconductor layer 180. A target including indium, gallium, or zinc may be disposed in the chamber.

As described above, the sputtering gas may include inert gas (e.g., argon (Ar)) and oxygen gas (O₂). In this case, a volume of the oxygen gas (02) included in the sputtering gas may occupy about 5% to about 70% of a volume of the chamber, and preferably, a volume of the oxygen gas (02) included in the sputtering gas may occupy about 10% to about 20% of a volume of the chamber. That is, a volume ratio of the oxygen gas to the inert gas (argon (Ar)) in the chamber may range from about 1:9 to about 2:8.

Likewise, an SCCM ratio of the oxygen gas (O₂) to the argon gas (Ar) injected into the chamber may range from about 1:19 to about 7:3, and preferably, an SCCM ratio of the oxygen gas (O₂) to the argon gas (Ar) injected into the chamber may range from about 1:9 to about 1:4 of a volume of the chamber.

As such, the oxide semiconductor layer 180 formed by performing a sputtering gas by sputtering gas including oxygen may have the second extinction coefficient having the maximum value of a positive number of about 0.0001 or less at a wavelength of about 550 nm. In this case, the second extinction coefficient may be less than the first extinction coefficient of the transparent electrode layer. The first extinction coefficient may be between about 0.05 and about 0.1 at about 550 nm.

A thickness of the oxide semiconductor layer 180 may be determined by a desired optical distance. In an embodiment, a thickness of the oxide semiconductor layer 180 may preferably be about 800 Å.

A thickness of the oxide semiconductor layer 180 may be greater than a thickness of the transparent electrode layer. In an embodiment, a thickness of the transparent electrode layer may preferably be 100 Å, for example. The reason why a thickness of the oxide semiconductor layer 180 is greater than a thickness of the transparent electrode layer is that a thickness of the oxide semiconductor layer 180 is determined by a desired optical distance. The oxide semiconductor layer 180 thicker than the transparent electrode layer may absorb more light than the transparent electrode layer, and thus, may affect the image quality of the display apparatus.

Accordingly, an extinction coefficient of the oxide semiconductor layer 180 thicker than the transparent electrode layer may greatly affect the image quality of the display apparatus. Accordingly, it is preferable that the oxide semiconductor layer 180 has the second extinction coefficient that is a positive number of about 0.0001 or less at a wavelength of about 550 nm.

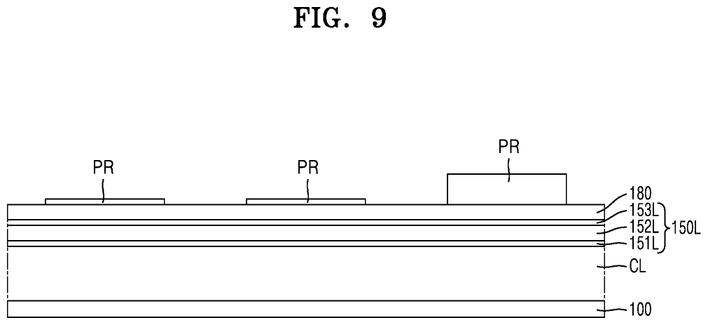

As shown in FIG. 9, the manufacturing method in the illustrated embodiment may further include forming a photoresist layer PR having a pre-determined pattern on the oxide semiconductor layer 180 by a halftone mask.

The forming of the photoresist layer PR having the pre-determined pattern may include adjusting a thickness of the photoresist layer PR corresponding to some of a plurality of pixel electrodes by an etching process using a halftone mask.

A patterning process applied to the photoresist layer PR is as follows. First, a negative photoresist may be applied to the oxide semiconductor layer 180, and then the photoresist may be exposed through a mask and developed. A first portion of the photoresist corresponding to a transmissive area of the mask remains thick without being removed, and a second portion corresponding to a blocking area of the mask is not exposed and thus is completely removed. Also, a thickness of a third portion for adjusting an exposure amount by applying the halftone mask may be less than a thickness of the first portion.

In an embodiment, a thickness of the photoresist layer PR disposed on the oxide semiconductor layer 180 to correspond to the first pixel electrode 150a may be greater than a thickness of the photoresist layer PR disposed on the 2-2^{th} transparent electrode layer 150b-3 to correspond to the second pixel electrode 150b, for example.

In an embodiment, a thickness of the photoresist layer PR disposed on the oxide semiconductor layer 180 to correspond to the first pixel electrode 150a may be greater than a thickness of the photoresist layer PR disposed on the 2-3^{th} transparent electrode layer 150c-3 to correspond to the third pixel electrode 150c.

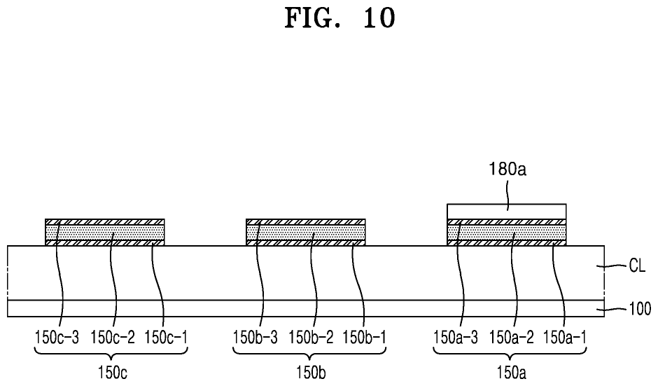

As shown in FIG. 10, the manufacturing method in the illustrated embodiment may further include forming the plurality of pixel electrodes including at least the first pixel electrode 150a and the second pixel electrode 150b, and the first oxide semiconductor layer 180a covering a top surface of the first pixel electrode 150a, by applying an etching process to the pixel electrode layer 150L and the oxide semiconductor layer 180.

In this case, the etching process may be a process of etching the first transparent electrode layer 151L, the reflective layer 152L, the second transparent electrode layer 153L, and the oxide semiconductor layer 180 by the photoresist layer PR having the pre-determined pattern.

In this case, the first oxide semiconductor layer 180a may refer to a layer obtained when the oxide semiconductor layer 180 covering a top surface of the pixel electrode layer 150L remains on the first pixel electrode 150a and covers a top surface of the first pixel electrode 150a after at least a part of the oxide semiconductor layer 180 is removed by an etching process.

That is, the plurality of pixel electrodes and the first oxide semiconductor layer 180a may be formed by a difference in a degree of etching due to a difference in a thickness of the photoresist layer PR.

As a result of the etching process, at least the 1-1^{th} transparent electrode layer 150a-1, the 1-2^{th} transparent electrode layer 150b-1, and the 1-3^{th} transparent electrode layer 150c-1 may be formed from the first transparent electrode layer 151L. The 1-1^{th} transparent electrode layer 150a-1, the 1-2^{th} transparent electrode layer 150b-1, and the 1-3^{th} transparent electrode layer 150c-1 may be disposed on the pixel circuit layer CL, and when viewed in a direction perpendicular to the substrate 100, may be spaced apart from each other in a direction parallel to a top surface of the substrate 100.

As a result of the etching process, at least the first reflective layer 150a-2, the second reflective layer 150b-2, and the third reflective layer 150c-2 may be formed from the reflective layer 152L. The first reflective layer 150a-2 may be disposed on the 1-1^{th} transparent electrode layer 150a-1, the second reflective layer 150b-2 may be disposed on the 1-2^{th} transparent electrode layer 150b-1, and the third reflective layer 150c-2 may be disposed on the 1-3^{th} transparent electrode layer 150c-1.

As a result of the etching process, at least the 2-1^{th} transparent electrode layer 150a-3, the 2-2^{th} transparent electrode layer 150b-3, and the 2-3^{th} transparent electrode layer 150c-3 may be formed from the second transparent electrode layer 153L. The 2-1^{th} transparent electrode layer 150a-3 may be disposed on the first reflective layer 150a-2, the 2-2^{th} transparent electrode layer 150b-3 may be disposed on the second reflective layer 150b-2, and the 2-3^{th} transparent electrode layer 150c-3 may be disposed on the third reflective layer 150c-2.

The 2-1^{th} transparent electrode layer 150a-3, the 2-2^{th} transparent electrode layer 150b-3, and the 2-3^{th} transparent electrode layer 150c-3 may be disposed on the pixel circuit layer CL, and when viewed in a direction perpendicular to the substrate 100, may be spaced apart from each other in a direction parallel to the top surface of the substrate 100.

As a result of the etching process, the first oxide semiconductor layer 180a may be disposed on the 2-3^{th} transparent electrode layer 150c-3. This is because the thick photoresist layer PR is formed on the oxide semiconductor by the halftone mask. Also, the oxide semiconductor layer may not be disposed or may not remain on the 2-1^{th} transparent electrode layer 150a-3 and/or the 2-2^{th} transparent electrode layer 150b-3. However, for convenience of explanation, the above description may be applied to an n^{th} pixel electrode and an n^{th} oxide semiconductor layer that may correspond to the n^{th} pixel electrode.

The 1-1^{th} transparent electrode layer 150a-1, the first reflective layer 150a-2, and the 2-1^{th} transparent electrode layer 150a-3 may correspond to the first pixel electrode 150a described in an embodiment of the display apparatus. The first oxide semiconductor layer 180a may be disposed on the 2-1^{th} transparent electrode layer 150a-3 corresponding to the first pixel electrode 150a.

The 1-2^{th} transparent electrode layer 150b-1, the second reflective layer 150b-2, and the 2-2^{th} transparent electrode layer 150b-3 may correspond to the second pixel electrode 150b described in the display apparatus. The 1-3^{th} transparent electrode layer 150c-1, the third reflective layer 150c-2, and the 2-3^{th} transparent electrode layer 150c-3 may correspond to the third pixel electrode 150c described in the display apparatus. The oxide semiconductor layer 180 may not be disposed on the 2-2^{th} transparent electrode layer 150b-3 corresponding to the second pixel electrode 150b and the 2-3^{th} transparent electrode layer 150c-3 corresponding to the third pixel electrode 150c.

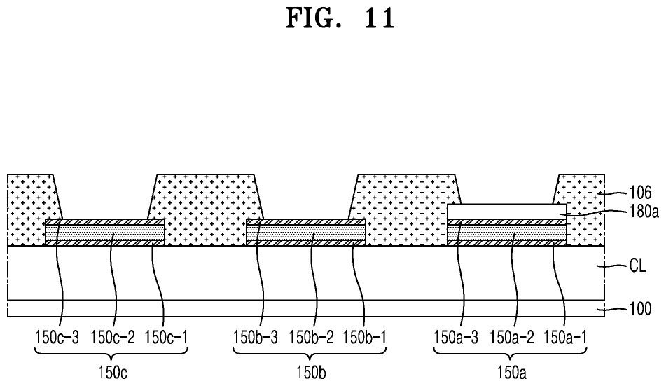

As shown in FIG. 11, the manufacturing method in the illustrated embodiment may further include forming a pixel-defining film 106 covering an edge of the second pixel electrode 150b and an edge of the first oxide semiconductor layer 180a, and exposing at least a central portion of the first oxide semiconductor layer 180a and at least a central portion of the second pixel electrode 150b.

That is, the forming of the pixel-defining film 106 may include forming the pixel-defining film 106 covering an edge of the oxide semiconductor layer, an edge of the 2-2^{th} transparent electrode layer 150b-3, and an edge of the 2-3^{th} transparent electrode layer 150c-3, after applying the etching process to the first transparent electrode layer 151L, the reflective layer 152L, the second transparent electrode layer 153L, and the oxide semiconductor layer 180.

That is, the pixel-defining film 106 may define a plurality of openings through which at least a central portion of the oxide semiconductor layer, at least a central portion of the 2-2^{th} transparent electrode layer 150b-3, and at least a central portion of the 2-3^{th} transparent electrode layer 150c-3 are exposed.

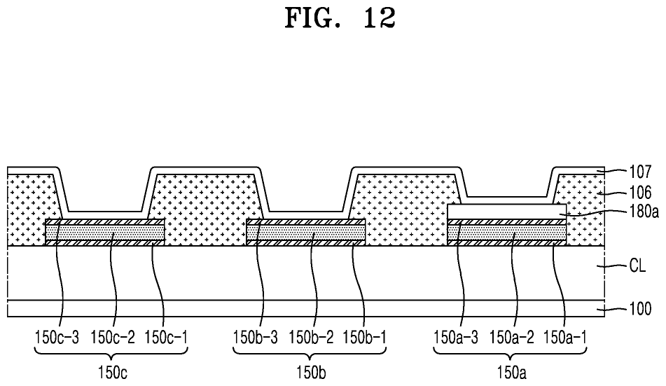

As shown in FIG. 12, the manufacturing method in the illustrated embodiment may include forming the metal oxide layer 107, after forming the pixel-defining film. The metal oxide layer 107 may be formed to cover an entirety of the surface. That is, the forming of the metal oxide layer 107 may include forming the metal oxide layer 107 covering at least a central portion of the first oxide semiconductor layer 180a, at least a central portion of the second pixel electrode 150b, and a top surface of the pixel-defining film.

The metal oxide layer 107 may be formed to cover a top surface of the pixel-defining film, at least a central portion of the oxide semiconductor layer, at least a central portion of the 2-2^{th} transparent electrode layer 150b-3, and at least a central portion of the 2-3^{th} transparent electrode layer 150c-3. The metal oxide layer 107 may cover an inner surface of each of the plurality of openings through which at least a central portion of the oxide semiconductor layer, at least a central portion of the 2-2^{th} transparent electrode layer 150b-3, and at least a central portion of the 2-3^{th} transparent electrode layer 150c-3 are exposed.

The metal oxide layer 107 may include tungsten oxide (WOₓ). When the metal oxide layer 107 includes tungsten oxide (WOₓ), holes may be more smoothly injected into an emission layer.

In an embodiment, the metal oxide layer 107 including tungsten oxide (WOₓ) may be deposited on an entirety of the surface without a separate etching process, and a thickness of the metal oxide layer 107 may be about 50 Å, for example. The metal oxide layer 107 including tungsten oxide (WOₓ) may prevent a driving voltage lagging phenomenon occurring in an oxide semiconductor layer including zinc (Zn).

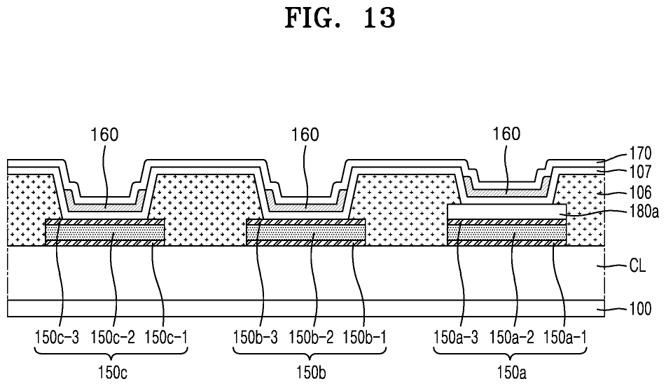

As shown in FIG. 13, the manufacturing method in the illustrated embodiment may further include forming an intermediate layer and the counter electrode 170 on the metal oxide layer 107, after forming the metal oxide layer 107. The forming of the intermediate layer and the counter electrode 170 may include forming the intermediate layer on the metal oxide layer 107 and forming the counter electrode 170 on the intermediate layer. The intermediate layer may include an emission layer corresponding to each pixel electrode.

In detail, the intermediate layer may include at least the first emission layer 160a, the second emission layer 160b, and the third emission layer 160c. The first emission layer 160a, the second emission layer 160b, and the third emission layer 160c may be disposed on the metal oxide layer 107. The first emission layer 160a, the second emission layer 160b, and the third emission layer 160c may be spaced apart from each other in a direction parallel to the top surface of the substrate 100 when viewed in a direction perpendicular to the substrate 100.

The first emission layer 160a may be disposed on the first pixel electrode 150a, the second emission layer 160b may be disposed on the second pixel electrode 150b, and the third emission layer 160c may be disposed on the third pixel electrode 150c. In detail, when viewed in a direction perpendicular to the substrate 100, the first emission layer 160a and the first pixel electrode 150a may overlap each other, the second emission layer 160b and the second pixel electrode 150b may overlap each other, and the third emission layer 160c and the third pixel electrode 150c may overlap each other.

Although not shown in FIGS. 7 to 13, the manufacturing method in the illustrated embodiment may be a method of manufacturing a display apparatus further including additional pixel electrodes and additional emission layers, in addition to the first pixel electrode 150a to the third pixel electrode 150c and the first emission layer 160a to the third emission layer 160c.

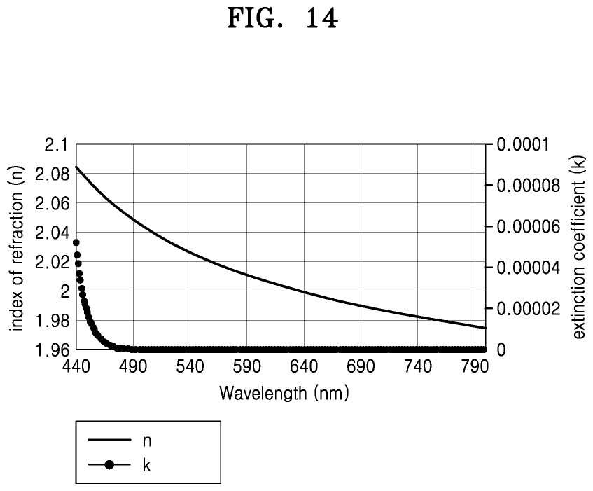

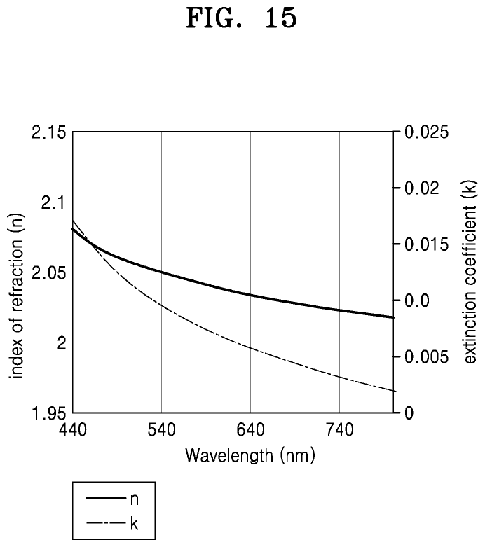

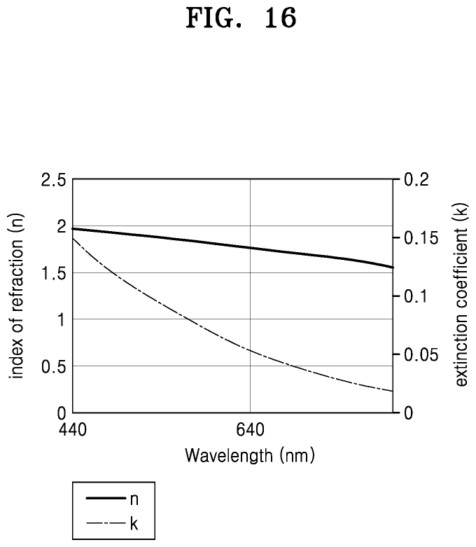

FIG. 14 is a graph showing a refractive index and an extinction coefficient of an oxide semiconductor layer included in a display apparatus of an embodiment according to a wavelength. FIG. 15 is a graph showing a refractive index and an extinction coefficient of IGZO of a comparative example according to a wavelength. FIG. 16 is a graph showing a refractive index and an extinction coefficient of ITO of a comparative example according to a wavelength.

As shown in FIG. 14, an extinction coefficient of the oxide semiconductor layer 180a or 180 formed according to the manufacturing method in the illustrated embodiment may be a value close to 0 in a range of about 490 nm to about 750 nm, and specifically, may be a positive number less than about 0.0001.

As shown in FIG. 16, an IGZO thin film according to a comparative example may be an IGZO thin film formed by sputtering gas not including oxygen gas. It is found that an extinction coefficient of the IGZO thin film according to the comparative example is a positive number greater than 0.005 in a range of about 490 nm to about 750 nm. However, a thickness of the IGZO thin film according to the comparative example is the same as a thickness of the oxide semiconductor layer 180a or 180 in FIG. 14, and other experimental conditions are the same.

As shown in FIG. 16, it is found that an extinction coefficient of an ITO thin film according to a comparative example is a positive number greater than 0.001 in a range of about 490 nm to about 750 nm. However, a thickness of the IGZO thin film according to the comparative example is the same as a thickness of the oxide semiconductor layer 180a or 180 in FIG. 14, and other experimental conditions are the same.

As shown in FIGS. 14 to 16, it is found that an extinction coefficient of the oxide semiconductor layers 180a and 180 formed according to the manufacturing method in the illustrated embodiment is much less than an extinction coefficient of the IGZO thin film and an extinction coefficient of the ITO thin film of FIGS. 15 and 16. Accordingly, when the oxide semiconductor layer 180a or 180 in the illustrated embodiment is used, light absorption in an optical resonance structure included in a display apparatus may be significantly reduced.

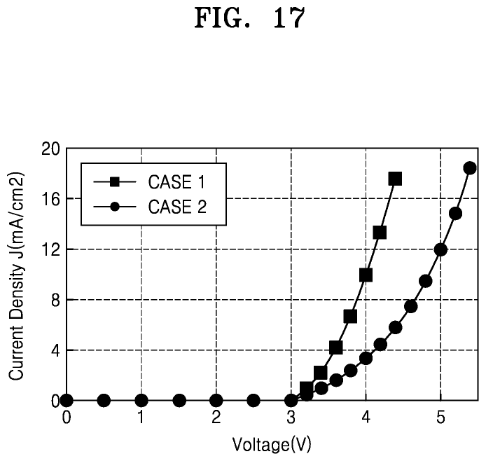

FIG. 17 is a graph showing electrical characteristics of a pixel electrode (case 1) included in an embodiment of a display apparatus and including a surface so that the metal oxide layer 107 including WOₓ is deposited on an entirety of the surface, and electrical characteristics of a pixel electrode (case 2) in which the metal oxide layer 107 is not deposited. However, in both cases, an IGZO thin film is formed on each pixel electrode.

Referring to FIG. 17, it is found that, in a case that the pixel electrode (case 1) included in an embodiment of the display apparatus includes a surface so that the metal oxide layer 107 is deposited on the entirety of the surface, the pixel electrode (case 1) is not affected by zinc (Zn) that may be generated when the IGZO thin film is formed. In comparison, it is found that the pixel electrode (case 2) in which an inorganic oxide is not deposited is affected by zinc (Zn) generated when the IGZO thin film is formed and thus, has relatively poor electrical characteristics. In detail, it is found that a current density (mA/cm²) of the pixel electrode in which the inorganic oxide is not deposited is lower than a current density of the pixel electrode in which the metal oxide layer 107 is deposited on the entirety of the surface at the same voltage (V). That is, when the metal oxide layer 107 including WOₓ is used, the pixel electrode may be protected from contamination by zinc (Zn), and thus, electrical characteristics of the pixel electrode may be maintained.

In addition, because WOₓ has a resistance value similar to that of a hole transport layer of an intermediate layer, even when the metal oxide layer 107 including WOₓ is deposited on an entirety of the surface, lateral leakage of current which may occur during entire surface deposition does not occur.

According to the embodiments, a display apparatus in which a decrease in light efficiency caused by an optical resonance structure is minimized and a method of manufacturing the display apparatus may be provided. However, the scope of the disclosure is not limited by these effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by one of ordinary skill in the art that various changes in form and details may be made therein without departing from the spirit and scope as defined by the following claims.

What is claimed is:

1. A display apparatus comprising:
a substrate;
a first pixel electrode disposed on the substrate and comprising a transparent electrode layer having a first extinction coefficient at a pre-determined wavelength;
a counter electrode disposed on the first pixel electrode;
a first emission layer disposed between the first pixel electrode and the counter electrode; and
a first oxide semiconductor layer disposed between the first pixel electrode and the first emission layer, and having a second extinction coefficient less than the first extinction coefficient at the pre-determined wavelength.

2. The display apparatus of claim 1, wherein the second extinction coefficient is a positive number of about 0.0001 or less at a wavelength of about 550 nanometers.

3. The display apparatus of claim 2, wherein the transparent electrode layer comprises indium tin oxide, and the first oxide semiconductor layer comprises indium gallium zinc oxide.

4. The display apparatus of claim 1, wherein a thickness of the first oxide semiconductor layer is greater than a thickness of the transparent electrode layer.

5. The display apparatus of claim 1, further comprising a metal oxide layer disposed between the first oxide semiconductor layer and the first emission layer.

6. The display apparatus of claim 5, wherein the metal oxide layer comprises tungsten oxide (WOₓ).

7. The display apparatus of claim 5, wherein a thickness of the metal oxide layer is less than a thickness of the first oxide semiconductor layer.

8. The display apparatus of claim 5, wherein the metal oxide layer contacts a top surface of the first oxide semiconductor layer.

9. The display apparatus of claim 1, wherein the transparent electrode layer comprises:
a 1-1^{th} transparent electrode layer disposed on the substrate;
a first reflective layer disposed on the 1-1^{th} transparent electrode layer; and
a 2-1^{th} transparent electrode layer disposed on the first reflective layer and comprising a same material as a material of the 1-1^{th} transparent electrode layer.

10. The display apparatus of claim 5, further comprising:
a second pixel electrode disposed on the substrate, spaced apart from the first pixel electrode in a direction parallel to a top surface of the substrate, and disposed under the counter electrode; and
a second emission layer disposed between the second pixel electrode and the counter electrode.

11. The display apparatus of claim 10, wherein the metal oxide layer is disposed between the second pixel electrode and the second emission layer.

12. The display apparatus of claim 10, wherein a distance between the first emission layer and the top surface of the substrate is greater than a distance between the second emission layer and the top surface of the substrate.

13. The display apparatus of claim 11, wherein the metal oxide layer contacts a top surface of the second pixel electrode.

14. The display apparatus of claim 10, further comprising a pixel-defining film covering an edge of each of the first pixel electrode and the second pixel electrode.

15. The display apparatus of claim 14, wherein the metal oxide layer covers a top surface of the pixel-defining film.

16. A method of manufacturing a display apparatus, the method comprising:
forming a pixel circuit layer comprising a thin-film transistor on a substrate;
forming, on the pixel circuit layer, a pixel electrode layer comprising a transparent electrode layer having a first extinction coefficient at a pre-determined wavelength;
forming, on the pixel electrode layer, an oxide semiconductor layer having a second extinction coefficient less than the first extinction coefficient at the pre-determined wavelength; and
forming a plurality of pixel electrodes comprising at least a first pixel electrode and a second pixel electrode, and forming a first oxide semiconductor layer covering a top surface of the first pixel electrode, by performing an etching process on the pixel electrode layer and the oxide semiconductor layer.

17. The method of claim 16, further comprising forming a pixel-defining film covering an edge of the second pixel electrode and an edge of the first oxide semiconductor layer and exposing at least a central portion of the first oxide semiconductor layer and at least a central portion of the second pixel electrode.

18. The method of claim 17, further comprising forming a metal oxide layer covering at least the central portion of the first oxide semiconductor layer, at least the central portion of the second pixel electrode, and a top surface of the pixel-defining film.

19. The method of claim 16, wherein the forming the oxide semiconductor layer comprises locating a target comprising indium, gallium, and zinc in a chamber, and performing a sputtering process using sputtering gas comprising inert gas and oxygen gas on the target.

20. The method of claim 19, wherein a volume ratio of the oxygen gas to the inert gas injected into the chamber ranges from about 1:9 to about 2:8.
